(19) United States
(12) Patent Application Publication
(10) Pub. No.: US 2010/0051909 A1
(43) Pub. Date: Mar. 4, 2010

(54) MOLECULAR ELECTRONIC DEVICES AND METHODS OF FABRICATING SAME

(76) Inventors: Shachar Richter, Mazkeret Batia (IL); Ariel Caster, Herzlia (IL); Elad Mentovich, Haifa (IL)

Correspondence Address: MARTIN D. MOYNIHAN d/b/a PRTSI, INC., P.O. BOX 16446, ARLINGTON, VA, 22215, US

(21) Appl. No.: 12/305,011

(22) PCT Filed: Jun. 19, 2007
(86) PCT No.: PCT/IL2007/000745

§ 371 Date: Jul. 8, 2009

Related U.S. Application Data
(60) Provisional application No. 60/814,590, filed on Jun. 19, 2006.

(51) Int. Cl. H01L 51/10; H01L 51/40

(52) U.S. Cl. 257/40; 438/99; 257/E51.002; 257/E21.158; 977/773

(57) ABSTRACT

Substrates carrying many molecular devices and circuits made of at least two devices are described. The substrates have less than 50% shorted molecular devices; and molecular circuits comprise a first molecular device and a second molecular device. The first molecular device has at least one self assembled monolayer (SAM) of a first type sandwiched between a first bottom electrode and a first top electrode. Similarly, the second molecular device has at least one SAM of a second type sandwiched between a second bottom electrode and a second top electrode. The first top electrode is electrically connected to the second bottom electrode. In exemplary embodiment, the first and second types of SAM are mutually different.

### FIELD OF THE INVENTION

The invention relates to molecular electronic devices and circuits, and also to methods of their fabrication.

### BACKGROUND OF THE INVENTION

Molecular Electronics is the field of science and technology in which one attempts to replace existing electronic devices with molecular moieties. The concept of molecular electronics suggests considerable size reduction of electronic components, due to usage of molecular-level control of electrical properties of electrical devices. Molecular electronics provides a means to extend Moore's Law (that the number of transistors on an integrated circuit for minimum component cost doubles every 24 months) beyond the foreseen limits of small-scale conventional silicon integrated circuits.

It was previously demonstrated that molecular layers can exhibit exciting electrical properties and can be potentially used for switching, memory amplification and quantum computing applications. However, despite of the impressive progress made in this field, there still remains a widely recognized need for, and it would be highly advantageous to have, a reliable method of making molecular-based electronic devices or circuits.

Some molecular devices are made of a molecular layer sandwiched between two metal electrodes are described, for instance, in:

Chen J., L. C. Calvet, M. A. Reed, D. W. Carr, D. S. Grubisha and D. W. Bennett, Chem. Phys. Lett. 313 741-748 (1999);

Chen J., Reed M. A., Rawlett A. M. and Tour, J. M., Science 1999, 286, 1550-1552;

Chen, J., Wang W., Reed M. A., Rawlett A. M., Price D. W., and Tour J. M., Appl. Phys. Lett. 2000, 77, 1224-1226; and

Green J E at el. NATURE 445 (7126): 414-417 Jan. 25, 2007.

The configuration of a molecular layer sandwiched between two metal electrodes is very challenging, and indeed, molecular devices of this kind are usually made at about 10% yield of functioning devices, in other words, about 90% of the devices are made shorted.

### SUMMARY OF THE INVENTION

One possible reason for the low yield obtained in related works is that during deposition of an electrode above the molecular layer, some of the deposited particles of this electrode penetrate through the molecular layer to the electrode underneath it, and short the device. Another possible reason, is that the deposition of atoms on the molecular layer, causes this layer a shockwave and/or thermal damage, that changed the molecular layer as not to function properly.

An aspect of some embodiments of the invention relates to a method of making molecular devices at high yield. In an exemplary embodiment of the invention the yield is 50%. Some other exemplary embodiments provide even higher yields, for example, 60%, 70%, or 80%. The recited yield is the ratio of functioning devices out of all the devices fabricated on a single substrate. Functioning of a device may be defined in various ways, depending on the device itself, nevertheless, a shorted device is not considered herein to be functioning. A device is shorted if it exhibits ohmic behavior (i.e. linear relation between voltage and current), and resistance similar to that expected of a direct contact between the two electrodes, usually in the order of μA's. In accordance with preferred embodiments of the present invention, less than 50%, 40%, 30%, or 20% of the devices are shorted.

An aspect of some embodiments of the invention relates to a flat substrate, carrying a plurality of molecular devices, wherein less than 50% of the devices are shorted. In various embodiments the number of devices carried by a single substrate is between about 100 and about 1,000,000, with 10,000 to 100,000 being most typical. In preferred embodiments, the ratio of shorted devices is smaller than 40%, 30%, or 20%.

Another aspect of some embodiments of the invention relates to a molecular circuit comprising two or more interconnected molecular devices. In an exemplary embodiment, such molecular circuits are manufactured with a high yield. For instance, in exemplary embodiments less than 50%, 40%, 30%, or 20% of the devices comprised in the circuits are shorted.

Another aspect of some embodiments of the invention relates to a substrate carrying a plurality of molecular circuits, at least one of which comprises two or more interconnected molecular devices. In an exemplary embodiment, such molecular circuits are manufactured with a high yield. For instance, in exemplary embodiments less than 50%, 40%, 30%, or 20% of the devices comprised in the circuits are shorted.

Another aspect of some embodiments of the invention relates to a method of making a molecular circuit comprising two or more interconnected molecular devices.

Naturally, some embodiments of the invention embody more than one aspect of the invention.

Generally, the present invention concerns molecular devices made of at least one self assembled monolayer (SAM) of electrically active molecules sandwiched between two electrodes that are insulated from each other with an insulating layer.

In the context of the present invention, a self assembled monolayer (SAM) comprises a layer of molecules chemically adsorbed on a surface. A SAM may comprise additional molecules, adsorbed on the layer that is chemically adsorbed on the surface. SAMs of electrically active molecules interact with electrical current as a conductor, an insulator, a diode, or any other electrical element. Electrically active molecules are, for example molecules capable of affecting electron transfer either actively, by generating or accepting electrons upon application of a potential, or passively, by allowing or disallowing electron transfer therethrough.

Electrically active molecules capable of generating electrons upon application of a potential typically comprise one or more electron donating groups. Examples of electron donating groups include, without limitation, amine, thiol, hydroxy, hydrazine, oxime, phosphine, alkenyl and azide.

Electrically active molecules capable of accepting electrons upon application of a potential typically comprise one or more electron accepting groups. Examples of electron accepting groups include, without limitation, ammonium, phsophonium, nitrile, nitrate, sulfonyl, sulfonate.

Exemplary electrically active molecules that typically allow electron transfer therethrough include, for example, conjugated oligomers (see, Table 1, entries 2 and 3).

Exemplary electrically active molecules that typically disallow electron transfer therethrough include, for example, saturated hydrocarbons (see, Table 1, entry 1).

A SAM can be composed of molecules that include one or more electrically active fragments. By “fragment” it is meant a part of a molecule.

Fragments of molecules that are electrically active, and the electrical functionality thereof, are presented in table I below.

Preferably, the insulating layer has at least one small cavity, at which the electrode is exposed. The SAM is deposited within the at least one cavity. The exposed electrode areas are termed herein “active areas”. Optionally, direct electrical current can go from one electrode to the other only through the active areas. Optionally, direct electrical current cannot go from one electrode to the other, for example, when the molecular device is designed to function as a capacitor.

Some of the ways in which high yields of molecular devices or circuits are obtained in accordance with exemplary embodiments of the present invention are explained below, and others will be apparent to a skilled person from the detailed description that follows.

Self assembled monolayers tend to attach differently to grain surfaces and to grain boundaries, which are lines, separating surfaces of adjacent grains. In an exemplary embodiment of the invention, a molecular device is made with a minimal amount of grain-boundaries in the active area. In some embodiments, this improves the uniformity of the SAM, and makes penetration of conductive particles from the upper electrode through the SAM to the bottom electrode less likely. Optionally, decreasing grain boundaries in the active areas comprises making a molecular device with electrodes having roughness below 1 nm. Preferably, the electrode also has a large grain size, of at least 100 nm, optionally about 200 nm, and preferably about 300 nm.

In an exemplary embodiment of the invention, grain size is enlarged by annealing, that is, heating the electrode so as to enhance joining together of many small grains to fewer larger grains. However, if the circuit or the device already includes a SAM, care should be taken not to damage this SAM by overheating.

Optionally, decreasing grain boundaries in the active areas comprises making a device with a small active electrode area. It is generally preferred that the active area is about the size of the grain size or smaller, preferably 5 or 10 times smaller. Exemplary sizes of active areas in accordance with this embodiment are 300 nm, 200 nm, and 100 nm. In some embodiments of the invention, SAM is introduced into the cavity from the gas phase, and this allows using smaller cavities, for example, cavities of 50 nm, 40 nm, 20 nm, or any larger or intermediate size.

Having a small active area and/or large grain size decreases the number of grain-boundaries at the reactive area, and thus, may result in a smoother reactive area and higher yield.

In an exemplary embodiment of the invention, the electrodes are deposited in a manner that minimizes thermal damage to underlying SAMs, thus increasing the yield.

Optionally, minimizing thermal damage to an underlying SAM comprises depositing the electrodes and/or insulating layers using an indirect deposition technique. In indirect deposition, the temperature and/or momentum of the deposited atoms are decreased on the way from the atom source to the target in an extent protecting the SAM at the target from thermal damage or shockwave that may be caused by direct deposition.

In an embodiment of the invention, making molecular devices or circuits at high yield comprises enlarging the order within the SAM, such that a larger portion of the active area is covered with molecules that are aligned vertically inside the small cavity in the insulating layer.

Optionally, enlarging the order within the SAM comprises adsorbing the SAM in the cavity by a layer-exchange technique. In a layer-exchange technique, a layer of poorly adsorbing molecules is first adsorbed in the cavity, and then replaced with better-adsorbing molecules. The better adsorbing molecules replace the poorly adsorbed molecules, but the latter occupies adsorption sites, and this way prevents from the former to adsorb parallel to the surface of the electrode.

A preferred embodiment of the invention relates to a molecular circuit, comprising two or more interconnected molecular devices. Optionally, the two or more molecular devices comprise two or more different electrically active molecules. Optionally, each device has one type of electrically active molecules in its SAM.

Allowing having a single substrate with molecular devices that include SAMs of different types opens new possibilities in molecular electronics, in comparison to what was available when each substrate could have had on it devices of one type only.

### BRIEF DESCRIPTION OF THE DRAWINGS

The invention is herein described, with reference to the accompanying drawings. With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the Drawings:

FIGS. 1a-1d are schematic illustrations of molecular devices according to various embodiments of the invention;

FIG. 2 is an image of a substrate carrying a plurality of molecular device;

FIG. 3 is a flowchart of actions taken in fabricating a molecular device according to an embodiment of the invention;

FIGS. 4a-4e are schematic illustrations of a molecular device in different stages of fabrication, according to an embodiment of the invention;

FIGS. 5a and 5b are schematic illustrations of molecular circuits according to two embodiments of the invention;

FIG. 6 is a flowchart of actions taken in fabricating a molecular circuit according to an embodiment of the invention;

FIGS. 7a-7g are schematic illustrations of a molecular circuit in different stages of fabrication, according to an embodiment of the invention;

### DESCRIPTION OF EXEMPLARY EMBODIMENTS

The following detailed description includes subtitles that are introduced only to help a reader in finding a description of a particular subject, and are not to be used for interpreting details or principles of the invention.

### Structure of a First Floor Device

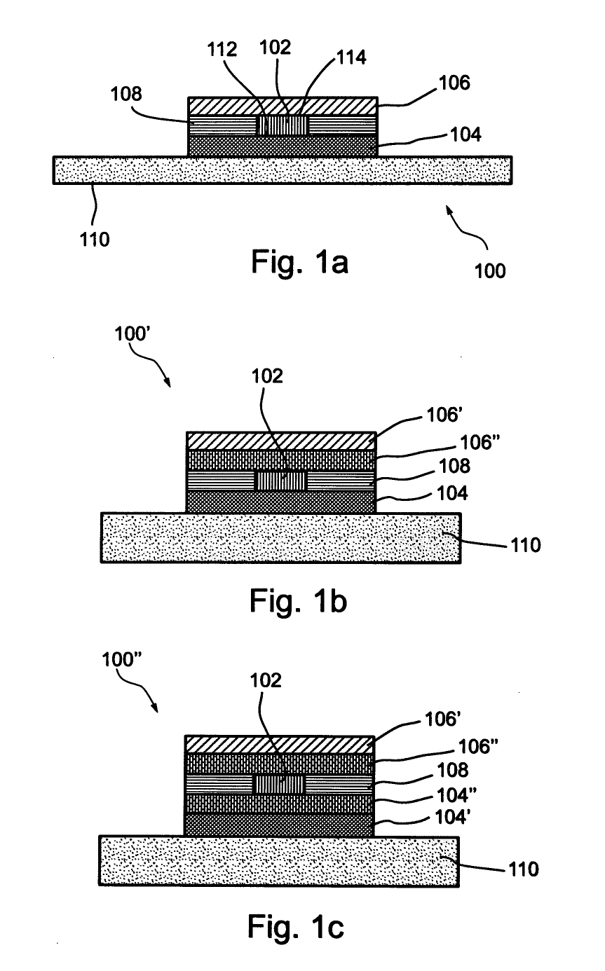

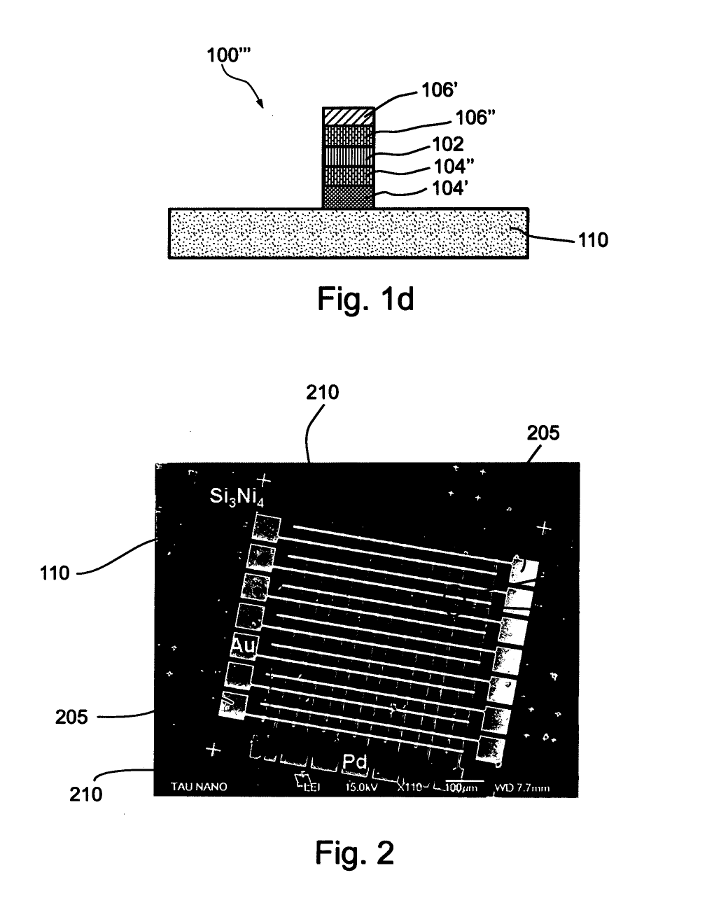

FIG. 1a is a schematic illustration of a molecular device 100 according to an embodiment of the invention. Device 100 comprises a self assembly monolayer 102 sandwiched between a bottom electrode 104 and a top electrode 106. The bottom electrode and the top electrode are insulated from each other with an insulating layer 108, having a cavity, within which SAM 102 is lying. The cavity defines on the bottom and top electrodes active areas 112 and 114, respectively. The entire device 100 is optionally carried on a silicon wafer 110, covered with a thermal oxide layer (not shown).

The terms top electrode and bottom electrode are used herein for convenience only, to denote on which electrode the SAM is introduced (on the bottom one), and which electrode is made when the SAM is already at place (the top one). The terms top and bottom are not intended to denote any particular spatial relationship between the electrodes. In some embodiments, however, these terms coincide with spatial relationships between the electrodes during the preparation of the device or circuit.

Optionally, the top and/or bottom electrode comprise a metal, for instance gold, palladium, platinum, silver, aluminum, or copper. Optionally, the top an/or bottom electrode comprise a semi-conductive substance, for instance, silicon. A carbon electrode, or electrodes made of carbon nano-tubes, fullerenes, etc can also be used. Optionally, the top and/or bottom electrode comprise a conductive glass, for instance indium titanium oxide (ITO) or fluoro titanium oxide (FTO). Optionally, the top and/or bottom electrode comprise a conductive polymer, for instance, polythiophene or Poly(3,4 ethylenedioxythiophene) poly(styrenesulfonate) (PEDOT:PSS).

Generally, for bottom electrodes it is preferable to use substances that provide layers with large grain size, and for top electrodes it is preferable to use substances that have small tendency to diffuse into the SAM.

Exemplary molecule fragments, suitable as building blocks for molecules to be used in SAMs are provided in Table 1 below:

TABLE 1

| | Molecule | | |
|---|---|---|---|
| | Fragment | Fragment's | |
| | Types | function | Exemplary Chemical Structures |
| 1. | Aliphatic Hydrocarbon and Perfluorinated Chains | Insulators, Barriers | 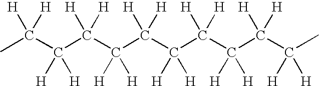 |
| | | | 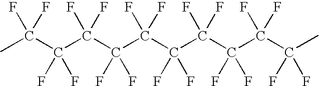 |
| 2. | Conjugated Oligomers | Molecular Wires | 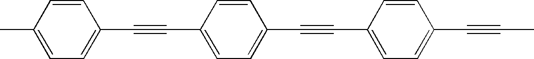 |
| | | | 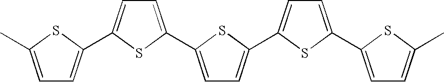 |
| 3. | Aromatic Rings | Molecular Wires and Junctions | 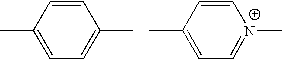 |
| | | | 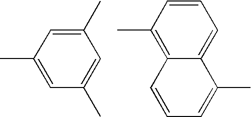 |
| 4. | Thiols, Isocyanides, Siloxanes etc. | Interface Connecting Components | 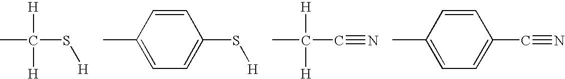 |
| 5. | Fullerenes and Ferrocenes | Molecular Memory Components, SET | 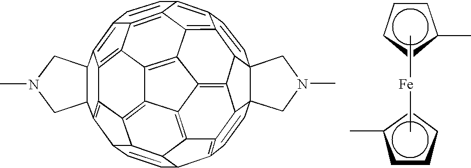 |
| 6. | Spiropyran and dithienylcyclo- pentenes | Optical Switches | 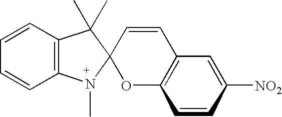 |
| | | | 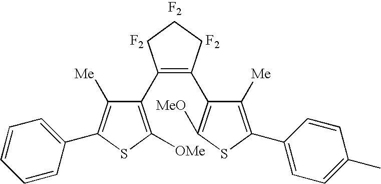 |

In various embodiments of the invention, SAMs comprise molecules containing one or more of the above fragments. For instance, in one experiment, a SAM made of a molecule consisting of Ferrocene fragment, (see raw 5 in table 1), connected to an aliphatic chain in each side, and having a thiol group (see raw 4 in table I) at the end of one of the aliphatic chains, was used.

Exemplary substances suitable as dielectric layers, either as part of the electrodes or as an insulating layer between the electrodes are: silicon nitride, aluminum oxide, silicon dioxide, epoxies (for example SU8), and dielectric polymers, (for instance, PMMA). Generally, it is preferred to use a dielectric layer having one or more of the following qualities: dielectric constant larger than 1, preferably between 2 to 5, uniformity, low roughness, low electrical traps and defects and low temperature deposition.

FIG. 1b is a schematic illustration of a molecular device 100′ according to another embodiment of the invention. Device 100′ has the same components as device 100, but the electrode 106 has two layers: an electrically conductive layer (106′) and an insulating, dielectric, layer (106″).

FIG. 1c is a schematic illustration of yet another molecular device, 100″, according to an embodiment of the invention. Device 100″ has the same components of device 100′, but here the bottom electrode is also made of two layers: 104′, which is conductive, and 104″, which is dielectric. Layers 104″ and 106″ are optionally of different thicknesses. For instance, the bottom electrode dielectric layer may be about 1 nm, to allow tunneling therethrough, while the top electrode dielectric layer may be about 30 nm.

FIG. 1d is a schematic illustration of yet another molecular device according to an embodiment of the invention. The device of FIG. 1d comprises a bottom electrode (made of parts 104′ and 104″) that is small enough to allow a SAM to cover it all in a uniform way. Optionally, the bottom electrode is 300 nm in width. In this embodiment, insulating layer 108 is optionally omitted, and the entire capacitance is of a capacitor comprising the SAM between the two layers.

### A Substrate Carrying a Plurality of Molecular Devices

FIG. 2 is an image of a substrate (110) carrying a plurality of molecular devices. The figure shows devices arranged in the well-known cross-board configuration. Pads 205 are contacts for electrifying the bottom electrodes, which go substantially horizontally across the figure, and pads 210 are for electrifying the top electrodes, going substantially vertically across the figure. The bottom at every crossing point of a top and bottom electrode there is a device, with a SAM in between, but the SAM is not visible in the picture, as it is hidden below the top electrode.

In an experiment made with the device, the image of which is provided in FIG. 2, the molecule HO(CH₂)₁₁-Ferrocene-(CH₂)₁₁SH, comprising a Ferrocene moiety chemically bound to two saturated organic chains, was used for the SAM. Much less than 15% of the devices were found to be shorted. Over 85% of the devices showed the electrical behavior that was theoretically expected to be demonstrated by a non-shorted device of this kind, namely, showing two dominate NDR peaks around 0.5 and 0.9 volts.

### Making a One Floor Device

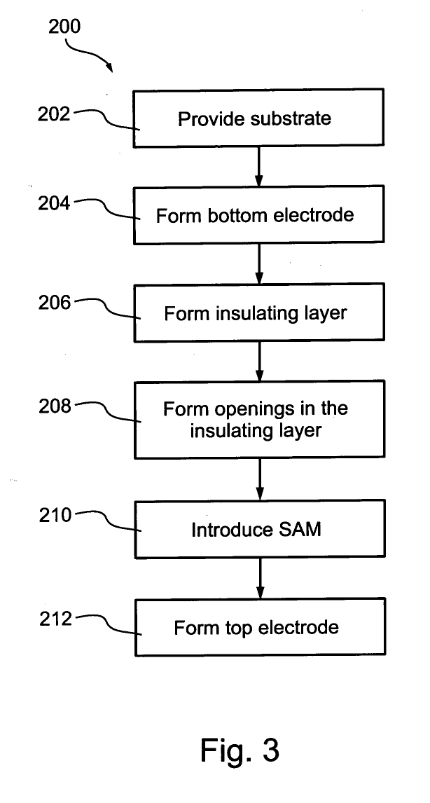

FIG. 3 is a flowchart of actions taken in fabricating the molecular device 100 of FIG. 1 in accordance with a method 200 according to an embodiment of the invention. FIGS. 4a-4e are schematic illustrations of the device in the different stages of fabrication.

Referring to FIG. 3, a substrate (110) is provided in 202. Substrate 110 preferably has smooth surface, and is preferably of a kind suitable for lithography. Some examples of suitable substrates are a semiconductor wafer made of, for instance, Si, GaAs, InP, or the like, and a plate made of plastic, quartz, etc.

In 204, a bottom electrode (104) is formed on the substrate (See FIG. 4a). In an embodiment of the invention, the bottom electrode is made of gold. Optionally it is about 150 nm thick. Deposition of the bottom electrode may be carried out in any known deposition method, for instance, soft lithography, imprint lithography, electroless plating, electron beam evaporation, thermal evaporation, or sputtering.

Optionally, a conductive layer is first formed to cover the entire substrate, and then, the structure of the electrode is defined, optionally, using image reversal photolithography. Optionally, the electrodes are defined as a cross-bar configuration, as depicted, for instance in FIG. 2.

Optionally, forming the bottom electrode (104) comprises annealing the electrode to enlarge the grain size and enhance the smoothness of the electrode. In the case of 150 nm grain size of gold layer, heating to 350° C. at a rate of 5° C./min resulted in grain size of about 300 nm.

Optionally, forming the bottom electrode comprises first forming an adhesion layer and then an electrically conductive layer, to obtain a structure as illustrated in FIG. 1b.

Optionally, the bottom electrode (104) is made of two layers: an adhesion layer, and an electrically active layer. The adhesion layer is made to improve adhesion of the electrically active layer to the substrate. For example, when the substrate is a silicon wafer and the conducting layer is gold, the adhesion layer may be a 10 nm thick Titanium layer.

The electrically active layer is preferably made of a substance that is suitable for creation of the SAM. For example, electrically conductive layer may be a 150 nm thick gold layer, and the SAM may be made of dithiols. Alternatively, the electrically conductive layer can be made of silica and the SAM can comprise a sylil group that attaches to the silica. Further alternatively, the electrically conductive layer can be made of copper and the SAM can comprise an amine group that attaches to the copper. Similarly, SAMs having various functional groups that have high affinity to the conductive layer can be used.

In 206, an insulating layer (108) is formed on top of the bottom electrode (See FIG. 4b). The insulating layer may be deposited, for instance, by plasma enhanced chemical vapor deposition (PE-CVD), spin coating, and/or Langmuir-Blodget coating.

Optionally, the insulating layer comprises Al₂O₃, Si₃N₄, SiO₂, polymethyl metacrylate (PMMA), a fatty acid, and/or modified nanoparticles of insulating materials.

In 208, openings are formed at the insulating layer covering each of the bottom electrodes (see FIG. 4c). Each cavity exposes a small portion of the underlying bottom electrode. Optionally, the cavity is defined using Reactive Ion Etching techniques.

In 210 a SAM (102) is introduced into the cavity formed in 208 (see FIG. 4d). Optionally, the SAM is introduced using a layer exchange technique, as this is described by Meshulam et al. in Small, 2005 volume 1, No. 9-9, p. 848-851, the contents of which is incorporated herein by reference. It is believed that at least when the SAM molecules are linear and have two ends, and have at both their ends linking groups that are capable of linking to the bottom electrode, the layer exchange technique produces more uniform layers, and thus help in obtaining the devices in a higher yield than available with some other methods.

In 212, a top electrode (106) is formed on top of the SAM (See FIG. 4e). To obtain the devices at high yield, forming the top electrode preferably comprises indirect deposition of a conductive substance, such as a metal, onto the SAM and the surrounding insulating layer (108). Indirect deposition is optionally applied as described in J. Phys. Chem. C Vol. 111 No. 5 (2007), pages 2318-2329, incorporated herein by reference.

Optionally, the indirect deposition is applied with cooling the formed molecular device, for instance, with a cryogenic fluid, for example, liquid nitrogen. Preferably, forming the top electrode comprises monitoring the temperature of the formed device, and controlling it to be below a certain threshold. For instance, if the SAM comprises a protein, it is preferable not to let the temperature to rise to the denaturation temperature of the protein. More generally, it is preferable to keep the temperature below a level at which the SAM might undergo conformational changes, which might reduce the yield. Preferably, the temperature is controlled to be less than about 150° C., more preferably less than about 50° C.

Optionally, the top electrode comprises palladium, titanium, carbon or any other substance known to have a low tendency to penetrate into SAMs.

Optionally, forming the top electrode comprises wet deposition of metallic nanoparticles, for instance, gold nanoparticles on the SAM. The gold (or any other suitable substance, such as silver or palladium, may further protect the SAM from interpenetration of adsorbed molecules, and thus contribute to obtaining the devices with higher yield. Optionally, after wet deposition of nanoparticles on the SAM, an electrode is deposited from vapor phase, optionally using an indirect deposition method, with the nanoparticles protecting the SAM from interpenetration by the vapor.

In exemplary embodiments of the invention, one or both of the bottom and top electrode includes a dielectric layer, as, for example, when the device is a molecular capacitor. In an exemplary embodiment of this kind, forming the bottom electrode comprises forming a conducting layer, as in step 204, and then forming above it an insulating layer as described above in 206. However, in 208, cavities are formed without exposing a conductive surface. This way, the SAM is introduced on the insulating layer. Optionally, before a dielectric layer is deposited as a top electrode, another dielectric layer is deposited, as to insulate the SAM from the conducting layer of the top electrode. The deposition of the dielectric layer component of the top electrode is preferably with indirect deposition.

### Structure of a Two-Floor Circuit

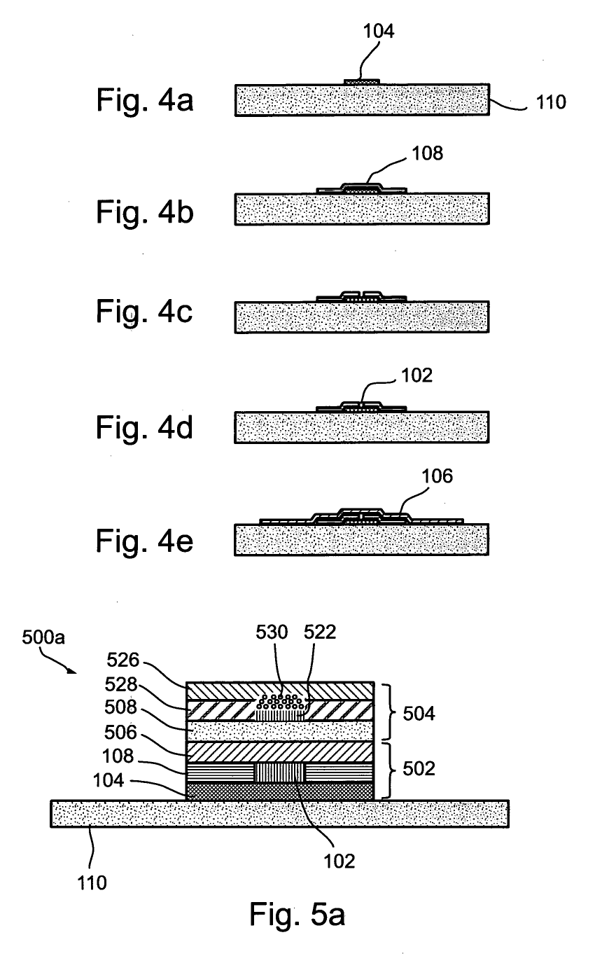

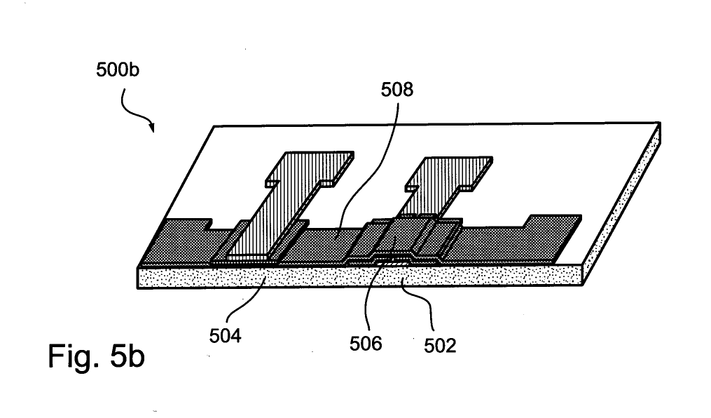

FIGS. 5a and 5b are schematic illustrations of molecular circuits (500a and 500b) according to two embodiments of the invention. Both embodiments include a first molecular device (502) and a second molecular device (504), and the top electrode (506) of the first molecular device is electrically connected to the bottom electrode (508) of the second molecular device. In FIG. 5a the second molecular device is on top of the first one, while in FIG. 5b the first and second molecular devices lie at about the same height above the substrate.

Going in more details into FIG. 5a, first molecular device 502 is similar in structure to device 100 of FIG. 1a. Shown are the self assembly monolayer 102, sandwiched between a bottom electrode 104 and a top electrode 506. The bottom electrode and the top electrode are insulated from each other with an insulating layer 108, having a cavity, within which SAM 102 is lying. The entire device 502 is carried on a substrate 110.

The second floor device, 504 comprises a SAM 522 sandwiched between a bottom electrode 508, and a top electrode 526.

Bottom electrode 508 is optionally made of a conducting layer deposited on the top electrode (506) of the first floor device, 502. Alternatively, the top electrode of the first floor device serves as the bottom electrode of the first floor device, and SAM 522 is deposited directly on the first floor upper electrode (506). However, in an embodiment where the bottom electrode (508) is chosen to facilitate self assembly of the active molecules in SAM 522, and upper electrode 506 is chosen to minimize interpenetration into the SAM 102, it may be preferable to use different substances as a top electrode in the first floor and a bottom electrode in the second floor. For instance, it may be preferable to use gold as a bottom electrode 508 and palladium as a top electrode 106.

Optionally, the molecules composing SAM 522 have different electrical behavior than those composing SAM 102. For instance, SAM 102 may be composed of electron donors, and SAM 522 of electron acceptors. Similarly, it is possible to choose for each floor SAM made of molecules that have electrical behavior of resistors, capacitors, conductors, switches, etc.

Preferably, bottom electrode 508 is not annealed, in order not to expose SAM 102 to heat. At the thickness of the layers making the circuit and the materials involved, it is usually impractical to heat the bottom electrode of the second floor device (508) without heating the SAM of the first floor device (102).

In embodiments where bottom electrode is not annealed it is preferred to make the active areas (and accordingly, the cavities in the insulating layer) even smaller than they are made above an annealed electrode layer. Preferable cavity sizes range between about 20 nm and about 50 nm. Alternatively or additionally, the cavity size is larger, and the SAM is of a kind that arranges vertically across large areas, for example, protein based SAMs or polymerized molecules based SAMs. Introduction of SAM 522 into such small cavities may be accomplished, for example, using layer exchange technique from the gas phase.

Bottom electrode 508 and top electrode 526 are separated from each other with an insulating layer 528. Preferably, insulating layer 528 is made of an insulating material that may be deposited with heating the substrate to mild temperature, as not to overheat SAM 102, which lays several layers underneath it. Alumina is an example of a suitable material, since it may be deposited with heating the sample to higher than 50° C., when indirect deposition is used. Alumina has another advantage, which is its high dielectric constant, which allows effective insulation with a relatively thin layer, of, for instance, 70 nm. Silicon oxide is another suitable choice.

On top of SAM 522, conducting nanoparticles 530 are shown. These may be, for instance, gold nanoparticles introduced via wet deposition. Having nanoparticles 530 may protect SAM 522 from direct impact of particles during the deposition of top electrode 526. The nanoparticles (530) are distinguishable from the top electrode (526) in the sense that their existence in the molecular device can be recognized, for instance, in (destructive or non-destructive) studies of the device.

A top electrode 526 is deposited on nanoparticles 530. Optionally, nanoparticles 530 are absent, and a top electrode 526 is deposited directly on the dielectric layer and SAMs, as shown in FIG. 1a.

### Making a Two (or More) Floor Circuit

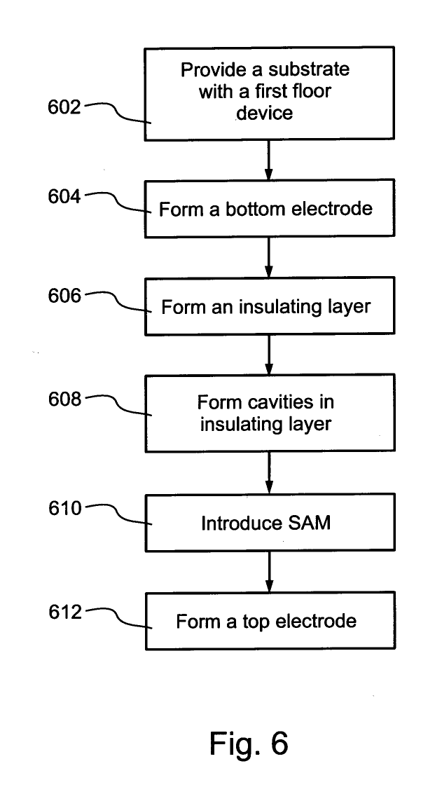

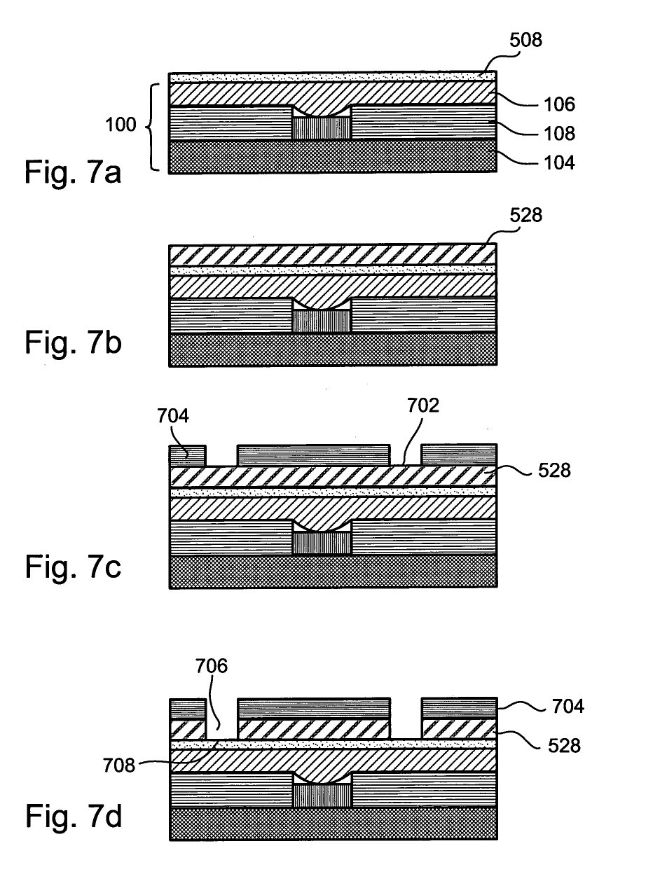

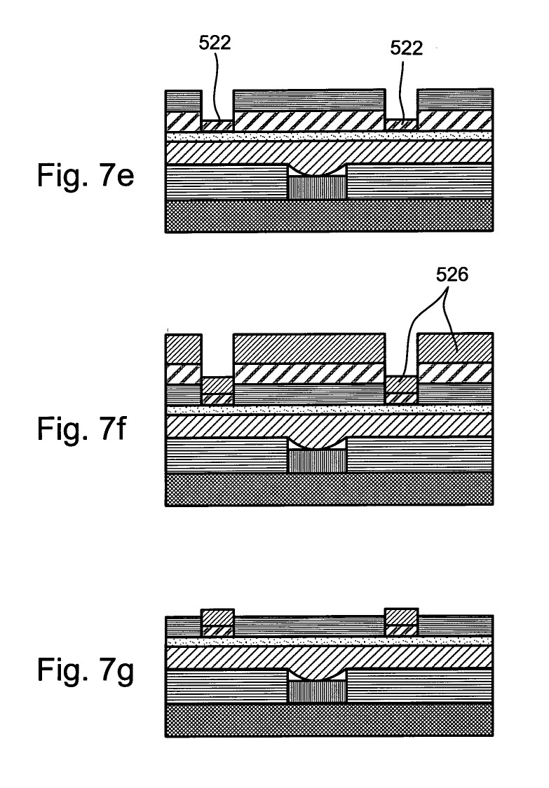

FIG. 6 is a flowchart of actions taken in fabricating the molecular circuit 500a or 500b of FIG. 5a or 5b in accordance with a method 600 according to an embodiment of the invention. FIG. 7 schematically illustrates a molecular circuit at different stages of fabrication according to method 600. Further devices may be fabricated on top of the circuits of FIG. 5a or 5b by carrying out method 600 repetitively.

In 602, a substrate with a molecular device comprising at least one floor is provided (see 100 in FIG. 7a. The white edge left in FIG. 7 between the SAM and the electrode above it is to illustrate that the bottom electrode not necessarily contact the entire SAM or completely fills the cavity-portion that is free of SAM). This may be fabricated, for example, using a method according to an embodiment of the invention, such as described in the context of FIG. 2.

Optionally, during the entire process of fabricating the second floor device, the temperature of the entire device is monitored, and controlled to be low enough as not to cause thermal damage to the SAM of the first and/or second floor. The maximal allowed temperature is as described in the context of temperature control during the making of the first floor device.

In 604, a bottom electrode (508, see FIG. 7a) is formed on the top electrode (106) of the first floor device (100). In an embodiment of the invention, the bottom electrode is absent, and the top electrode of the first floor device serves also as the bottom electrode of the second floor device.

Bottom electrode 508 is optionally made of gold. Optionally bottom electrode 508 is about 150 nm thick. Deposition of the bottom electrode preferably comprises indirect deposition, as this is described above in the context of depositing the top so electrode of the first floor device.

In 606, an insulating layer (528) is formed on top of the bottom electrode (See FIG. 7b). Forming the insulating layer optionally comprises indirect deposition to prevent damage to the SAM of the first floor (102). Alternatively or additionally, forming insulating layer 528 comprises low temperature PE-CVD, for instance, of alumina. Other methods available for forming the insulating layer include, for example, spin coating and Langmuir-Blodget coating.

In 608, cavities are defined at the insulating layer covering bottom electrode. Optionally, the cavities are defined both for creating the active areas that are to accept the SAM in a following stage and for pad connections for the first floor.

In this context defining a cavity means defining the position of the cavity and its dimensions. For instance, by applying to the insulating layer a photoresist mask (704 in FIG. 7c), such that when etching is applied, openings in the insulating layer will be created only at an openings in the mask.

Optionally, the definition of cavities comprises spin coating of the substrate with a photoresist, e.g. positive photoresist S1818™ and calibrated reactive ion etching. The defined cavities 706 are created, and expose active areas 702 at the upper surface of the top electrode 528 (see FIG. 7d). Cavities 706 are created, for instance, using calibrated reactive ion etching,

In 610 SAMs (522, see FIG. 7e) are introduced into the cavities formed in 208, on the active areas, optionally, using a layer exchange technique, optionally a gas-phase layer exchange, as described above.

In 612, a top electrode (526, FIG. 7f) is formed on top of the SAM, using an indirect deposition technique as described above, and then, top contact deposited above the photoresist is removed, together with the photoresist underneath it, with a lift-off technique, to obtain a molecular circuit as described, as shown in FIG. 7g.

Further devices may be created in further “floors” in similar methods.

### General

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination.

The terms “dielectric” and “insulating” are used in the specification interchangeably.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

1. A molecular circuit comprising a first molecular device and a second molecular device, said first molecular device having at least one self assembled monolayer (SAM) of a first type sandwiched between a first bottom electrode and a first top electrode, and said second molecular device having at least one SAM of a second type sandwiched between a second bottom electrode and a second top electrode, said first top electrode being electrically connected to the second bottom electrode.

2. A molecular circuit according to claim 1, wherein the first top electrode is the second bottom electrode.

3. A molecular circuit according to claim 1, wherein a SAM of at least one of said first and second types comprises organic molecules.

4. A molecular circuit according to claim 1, wherein a SAM of at least one of said first and second types comprises electrically active molecules.

5. A molecular circuit according to claim 4, wherein at least one of said electrically active molecules has at least one electron accepting group.

6. A molecular circuit according to claim 4, wherein at least one of said electrically active molecules has at least one electron donating group.

7. A molecular circuit according to claim 4, wherein at least one of said electrically active molecules has at least one electron donating group and at least one electron accepting group.

8. A molecular circuit according to claim 1, wherein said first and second types of SAM are different.

9. A molecular circuit according to claim 1, wherein in at least one of said first and second molecular devices the bottom and top electrodes are in electrical contact with each other only through the at least one SAM.

10. A molecular circuit according to claim 1, wherein in at least one of said first and second molecular devices the bottom and top electrodes with the at least one SAM therebetween form a capacitor.

11. A molecular circuit according to claim 1, wherein in at least one of said first and second molecular devices, at least one of said bottom and top electrodes comprises a conductive layer and a dielectric layer, the dielectric layer facing the at least one SAM.

12. A molecular circuit according to claim 11, wherein in at least one of said first and second molecular devices, at least one of said bottom and top electrodes comprises a conductive layer and a dielectric layer, said dielectric layer having a thickness sufficient to insulate the conductive layer from the at least one SAM.

13. A molecular circuit according to claim 11, wherein in at least one of said first and second molecular devices, at least one of said bottom and top electrodes comprises a conductive layer and a dielectric layer, said dielectric layer having a thickness which allows electron tunneling between the conductive layer and the at least one SAM.

14. A molecular circuit according to claim 1, wherein at least one of the top and bottom electrode of at least one of said molecular devices comprises at least one of gold, palladium, platinum, silver, ITO (indium titanium oxide), aluminum, silicon, and copper.

15. A molecular circuit according to claim 1, wherein in at least said first molecular device, the grain size of the bottom electrode is larger than 150 nm.

16. A molecular circuit according to claim 1, wherein in at least one of said first and second molecular devices, the SAM is electrically connected to the top electrode through nanoparticles of a conducting substance, said nanoparticles forming a layer distinguishable from said top electrode.

17. A molecular circuit according to claim 1, wherein at least one of said first and second molecular devices comprises:
a first SAM, sandwiched between the bottom electrode and a first portion of the top electrode,
a second SAM, sandwiched between the bottom electrode and a second portion of the top electrode,
and said first and second portions of the top electrode are in electrical contact with each other only through said first and second SAMs.

18. A method of making a molecular circuit which comprises a first molecular device and a second molecular device, said first molecular device having at least one self assembled monolayer (SAM) of a first type sandwiched between a first bottom electrode and a first top electrode, and said second molecular device having at least one SAM of a second type sandwiched between a second bottom electrode and a second top electrode, the method comprising:
(a) providing the first molecular device; and
(b) forming a second molecular device; said forming being performed such that said second bottom electrode is in electrical contact with said first top electrode.

19. A method according to claim 18, wherein said forming a second molecular device comprises:
(b1) forming an insulating layer on the top of the top electrode of the first molecular device;
(b2) forming an opening in said insulating layer so as to expose a portion of the top layer of the first molecular device;
(b3) forming the at least one SAM of a second type on the exposed portion of said first top electrode; and
(b4) forming the second top electrode on top of said insulating layer, such that at the opening, the second top electrode contacts the SAM of the second type without contacting the second bottom electrode.

20. A method according to claim 19, wherein forming the second molecular device comprises forming a conductive layer between the insulating layer formed in (b1) and the top electrode of the first molecular device.

21. A method according to claim 18, wherein forming at least one of the second bottom electrode and the second top electrode comprises indirect evaporation.

22. A method according to claim 20, wherein forming the second top electrode on top of the insulating layer comprises:
(b4.1) adsorbing nanoparticles of a conducting substance on top of the SAM such that the nanoparticles do not penetrate through the SAM; and
(b4.2) forming a top electrode on top of the insulating layer and the nanoparticles.

23. A method according to claim 22, wherein said adsorbing comprises adsorbing from solution.

24. A method according to claim 19, wherein forming an insulating layer comprises cooling at least the first molecular device.

25. A method according to claim 24, comprising monitoring the temperature of the first device not to exceed 150° C.

26. A method according to claim 28, wherein forming the top electrode of the second molecular device comprises indirect deposition.

27. A substrate carrying at least 100 molecular devices, wherein less than 50% of said devices are shorted.

28. A substrate according to claim 27, comprising at least one un-shorted device having a self assembled monolayer (SAM) sandwiched between a bottom electrode and a top electrode, the bottom and top electrodes being insulated from each other, such that direct electrical contact between the two electrodes can go only through the SAM.

29. A substrate according to claim 28, wherein said at least one un-shorted device has a bottom electrode with grain size of at least 150 nm.

30. A method of making a substrate carrying at least 100 molecular devices, less than 50% of which being shorted, the method comprising:
(a) forming on a substrate a bottom electrode;
(b) forming on the bottom electrode an insulating layer;
(c) forming at least one opening in the insulating layer for each of the plurality of devices so as to expose at least one closed portion of a bottom electrode;
(d) introducing a layer of self assembled molecules (SAM) into each of said at least one opening; and
(e) forming a top electrode on top of the insulating layer, such that at the at least one opening, the top electrode contacts the self assembled molecules without contacting the bottom electrode.

31. A method according to claim 30, wherein forming a top electrode comprises indirect deposition.

32. A method according to claim 30, wherein forming a top electrode comprises adsorbing on the SAM nanoparticles of a conducting material from a liquid phase.

33. A method according to claim 31, wherein forming a top electrode further comprises depositing at least on the nanoparticles a conducting layer from a vapor phase.

34. A method according to claim 30, wherein forming a top electrode comprises depositing on the SAM conductive nanoparticles in one deposition method, and depositing on the nanoparticles a conducting layer using a second deposition method.

35. A method according to claim 34, wherein said first deposition method comprises wet deposition.

36. A method according to claim 34, wherein said second deposition method comprises indirect deposition.

37. A method according to claim 30, wherein forming a bottom electrode comprises forming a conductive layer having particles with grain size of at least 150 nm.

38. A method according to claim 30, wherein forming a bottom electrode comprises annealing the bottom electrode.

39. A method according to claim 30, wherein forming an insulating layer comprises at least one of low temperature plasma enhanced chemical vapor deposition, spin coating, and Langmuir-Blodget coating.

40. A method according to claim 30, wherein introducing the SAM comprises layer exchange.

41. A method according to claim 40, wherein said layer exchange is gas-phase layer exchange.

42. A method according to claim 30, wherein said at least one opening is smaller than 300 nm in diameter.

43. A method according to claim 30, wherein said at least one opening is smaller than 200 nm in diameter.

44. A method according to claim 30, wherein said at least one opening is smaller than 100 nm in diameter.

45. A method according to claim 30, wherein said at least one opening is smaller than 50 nm in diameter.
